(19) United States
(12) Patent Application Publication
(10) Pub. No.: US 2026/0099456 A1
(43) Pub. Date: Apr. 9, 2026

(54) BUMP MAP FOR IMPROVED THERMALS IN A HIGH-BANDWIDTH MEMORY DEVICE

(71) Applicant: Micron Technology, Inc., Boise, ID (US)

(72) Inventors: Shailesh Kayambady Sathyanarayana Bhat, Folsom, CA (US); Raghukiran Sreeramaneni, Frisco, TX (US); Nevil N. Gajera, Meridian, ID (US); Raymond Chang, Sacramento, CA (US)

(21) Appl. No.: 19/349,880

(22) Filed: Oct. 3, 2025

Related U.S. Application Data
(60) Provisional application No. 63/705,448, filed on Oct. 9, 2024.

(51) Int. Cl. G06F 13/42; H01L 23/00; H01L 25/18; H10B 80/00; H10D 80/30

(52) U.S. Cl. CPC G06F 13/4221; H10B 80/00; H10D 80/30; H10W 90/00; H10W 90/26; H10W 90/297; H10W 90/724

(57) ABSTRACT

System-in-package (SiP) devices, and associated systems and methods are disclosed herein. In some embodiments, a SiP device can include a base substrate, as well as a host device and an improved-thermal high-bandwidth memory (HBM) device each integrated with the base substrate. The improved-thermal HBM device can include an interface die and a stack of one or more memory dies carried by the interface die. The interface die includes an input/output (IO) circuit, which is communicably coupled via one or more IO circuit interfaces to the host device through communication channels of the base substrate. The IO circuit interfaces of the improved-thermal HBM device distributes physical interconnect bumps for transmit data and receive data in a dispersed manner along an edge of the interface die in a manner to reduce the occurrence of thermal hotspots.

### CROSS-REFERENCE TO RELATED APPLICATION(S)

The present application claims priority to U.S. Provisional Ser. No. 63/705,448, filed Oct. 9, 2024, the disclosure of which is incorporated herein by reference in its entirety.

### TECHNICAL FIELD

The present technology is generally related to vertically stacked semiconductor memory devices and, more specifically, to systems and methods for reducing thermal hotspots within high-bandwidth memory devices of a system-in-package.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet market demands, semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet market demands, such as by reducing the overall device footprint, can often introduce challenges in other aspects, such as maintaining circuit robustness and/or failure detectability.

### BRIEF DESCRIPTION OF THE DRAWINGS

FIG. 1 is a partially schematic cross-sectional diagram of a system-in-package device.

FIG. 2 is an illustration of a bump map of a Universal Chiplet Interconnect Express interface of an HBM device in a system-in-package device.

FIG. 3 is an illustration of a bump map of a Universal Chiplet Interconnect Express interface of an HBM device, configured in accordance with some embodiments of the present technology, in a system-in-package device.

FIG. 4 is an illustration of a bump map of a Universal Chiplet Interconnect Express interface of an HBM device, configured in accordance with further embodiments of the present technology, in a system-in-package device.

FIG. 5 is an illustration of a bump map of a Universal Chiplet Interconnect Express interface of an HBM device, configured in accordance with still further embodiments of the present technology, in a system-in-package device.

FIG. 6 is a flow diagram of a process for manufacturing a system-in-package device in accordance with some embodiments of the present technology.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, lower power consumption, and reduced chip size are features that are demanded from semiconductor memory. In recent years, vertically stacked memory devices have been introduced, often referred to as 2.5-dimensional (“2.5D”) memory devices when placed adjacent to a host device. Some 2.5D memory devices are formed by stacking memory dies vertically and interconnecting the dies using through-silicon (or through-substrate) vias (TSVs). Benefits of the 2.5D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5D memory devices contribute to higher memory access speed, lower power consumption, and chip size reduction. Example 2.5D memory devices include Hybrid Memory Cube (HMC) and High-Bandwidth Memory (HBM) devices. For example, HBM devices are a type of memory that includes a vertical stack of dynamic random-access memory (DRAM) dies and an interface die (which, e.g., provides the interface between the DRAM dies of the HBM device and a host device).

In a system-in-package (SiP) configuration, HBM devices may be integrated with a host device (e.g., a graphics processing unit (GPU), a computer processing unit (CPU), a tensor processing unit (TCU), and/or any other suitable processing unit) using a base substrate (e.g., a silicon interposer, a substrate of organic material, a substrate of inorganic material and/or any other suitable material that provides interconnection between the host device and the HBM device and/or provides mechanical support for the components of a SiP device), through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., GPU/CPU/TCU) and HBM devices during operation. For example, the high-bandwidth channels can be on the order of 1000 gigabytes per second (GB/s, sometimes also referred to as gigabits (Gb)). As a result, the SiP device can quickly complete computing operations once data is loaded into the HBM devices. SiP devices, in turn, are typically integrated with a package substrate (e.g., a PCB) adjacent to other electronics and/or other SiP devices within a packaged system.

Market demands on SiP devices and/or the HBM devices therein can present certain challenges, however. One such challenge is that SiP devices are beginning to use more sophisticated interconnect interfaces with greater speeds for communication between the devices therein (for example, between HBM devices and host devices), without increasing in package size, thereby increasing power density within the SiP device and/or devices therein. For example, the Universal Chiplet Interconnect Express (UCIe) interconnect, which specifies a die-to-die interconnect standard, is expected to be used increasingly for communication between devices within a SiP. As a result, and as discussed in more detail below, traffic-heavy circuits in the HBM devices, such as input/output (“IO”) circuits in an interface die that implement the UCIe interface, can generate significant amounts of heat. The heat-generating challenges posed by IO circuits, and the UCIe interfaces therein, are made more significant due to the fact that the IO circuits (and UCIe interfaces therein) tend to be located on the HBM interface die edge that is closest to the host device with which the HBM device is communicating via the UCIe interface. As a result, the heat-generating IO circuits and UCIe interfaces may generate thermal hotspots that are concentrated on the HBM interface die edge closest to the communicating host device (also referred to as the “shoreline” or “shoreline edge”). If not mitigated, the heat can cause various deleterious effects on the HBM device, such as the degradation of communication channels, increased memory loss (requiring increased refresh rates and therefore more power), and/or the like.

The systems and methods described herein help address heat within the HBM devices, and/or within the SiP devices more generally, by reducing the concentration of thermal hotspots along the shoreline edge of the HBM interface die. For example, the HBM devices described herein include UCIe interfaces with improved-thermal bump maps. As described herein, the improved-thermal bump maps organize the bumps used for responding to host read commands (e.g., transmit data) and the bumps used for responding to host write commands (e.g., receive data) in a more distributed fashion within the overall floorplan of the bump map of the UCIe interface (as compared to conventional UCIe bump maps). The improved-thermal bump maps therefore distribute the activity at the UCIe interface (and IO circuits) over a greater floorplan region during reads and writes and thus reduce the concentration of thermal hotspots along the shoreline edge.

As used herein, the terms “vertical,” “lateral,” “upper,” “lower,” “top,” and “bottom” can refer to relative directions or positions of features in the devices in view of the orientation shown in the drawings. For example, “bottom” can refer to a feature positioned closer to the bottom of a page than another feature. These terms, however, should be construed broadly to include devices having other orientations, such as inverted or inclined orientations where top/bottom, over/under, above/below, up/down, and left/right can be interchanged depending on the orientation.

Although primarily discussed herein in the context of HBM devices with improved-thermal bump maps, one of skill in the art will understand that the scope of the invention is not so limited. For example, various components of the SiP devices described herein can also be implemented with improved-thermal bump maps. Further, although the improved-thermal bump maps are primarily discussed herein in the context of the UCIe interface, one of skill in the art will understand that the improved-thermal bump maps can be used for other die-to-die interconnects within SiP devices (for example, Advanced Interconnect Bus (AIB), High Bandwidth Interconnect (HBI), eXtra Short Reach (XSR), Very Short Reach (VSR), and the like). Accordingly, the scope of the invention is not confined to any subset of embodiments and is confined only by the limitations set out in the appended claims.

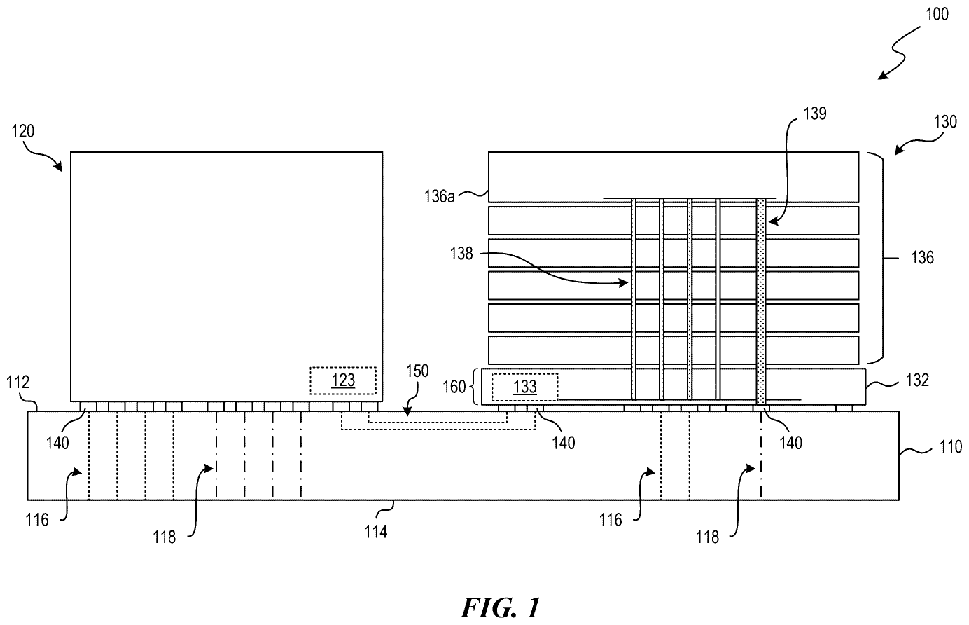

FIG. 1 is a partially schematic cross-sectional diagram of a SiP device 100. As illustrated in FIG. 1, the SiP device 100 includes a base substrate 110 (e.g., a silicon interposer, another organic interposer, an inorganic interposer, and/or any other suitable base substrate), as well as a host device 120 and an HBM device 130 each integrated with (e.g., carried by and coupled to) an upper surface 112 of the base substrate 110 through a plurality of interconnect structures 140 (three labeled in FIG. 1). The interconnect structures 140 can be solder structures (e.g., solder balls), metal-metal bonds, bumps, micro bumps, and/or any other suitable conductive structure that mechanically and electrically couples the base substrate 110 to each of the host device 120 and the HBM device 130. Further, the host device 120 is coupled to the HBM device 130 through one or more communication channels 150 formed in the base substrate 110 (sometimes referred to as a SiP bus). The communication channels 150 can include one or more route lines (two illustrated schematically in FIG. 1) formed into (or on) the base substrate 110.

As further illustrated in FIG. 1, the base substrate 110 includes a plurality of external signal TSVs 116 and a plurality of external power TSVs 118 extending between the upper surface 112 and a lower surface 114 of the base substrate 110. The external signal TSVs 116 can communicate signals (e.g., data, control signals, processing commands, and/or the like) between the host device 120 and/or the HBM device 130 and an external component (e.g., a PCB the base substrate 110 is integrated with, an external controller, and/or the like). The external power TSVs 118 provide electrical power to the host device 120 and/or the HBM device 130 from an external power source.

The host device 120 can include a variety of components, such as a processing unit (e.g., CPU/GPU/TCU), one or more registers, one or more cache memories, and/or a variety of other components (not shown). In the illustrated environment, the host device 120 additionally includes a host IO circuit 123 that can direct signals to and/or from the HBM device 130 through the communication channels 150. Additionally, or alternatively, the host IO circuit 123 can direct signals to and/or from an external component (e.g., a controller coupled to one or more of the external signal TSVs 116 and/or the like).

The HBM device 130 can include an interface die 132 and a stack of one or more memory dies 136 (six illustrated in FIG. 1) carried by the interface die 132. The HBM device 130 also includes one or more signal TSVs 138 (four illustrated in FIG. 1) and one or more power TSVs 139 (one illustrated in FIG. 1) each extending from the interface die 132 to an uppermost memory die 136a. The power TSV(s) 139 provide power (e.g., received from one or more of the external power TSVs 118) to the interface die 132 and each of the memory dies 136. The signal TSVs 138 communicably couple each of the memory dies 136 to an IO circuit 133 in the interface die 132 (in addition to various other circuits in the interface die 132). In turn, the IO circuit 133 can direct signals to and/or from the host device 120 and/or an external component (e.g., an external storage device coupled to one or more of the external signal TSVs 116 and/or the like). As illustrated in FIG. 1, the IO circuit 133 may be located at and/or near an edge 160 of the interface die 132 that is closed to the host device 120 (i.e., the shoreline edge).

The IO circuit 133 may include one or more UCIe interfaces (not shown), each of which provides an independent interface between the HBM device 130 and the host device 120. For example, each UCIe interface may be used for communication between the host device 120 and one or more HBM channels of the HBM device 130. Further, each UCIe interface of the IO circuit 133 encompasses multiple signals that are used for communication between the HBM device 130 and host device 120 (e.g., via communication channels 150) and/or other devices of the SiP device 100. For example, each UCIe interface may include receive data (“rxdata”) signals used in response to a host write command, transmit data (“txdata”) signals used in response to a host read command, command signals, sideband information signals, power signals, and the like. As described herein, a “bump map” specifies the physical arrangement of those signals at the physical boundary of the UCIe interface. That is, the bump map describes which interconnect structures 140 (e.g., bumps, micro bumps, and the like) of the interface die 132 correspond to which UCIe signals (e.g., the bump location corresponding to a txdata signal, the bump location corresponding to a rxdata signal, etc.).

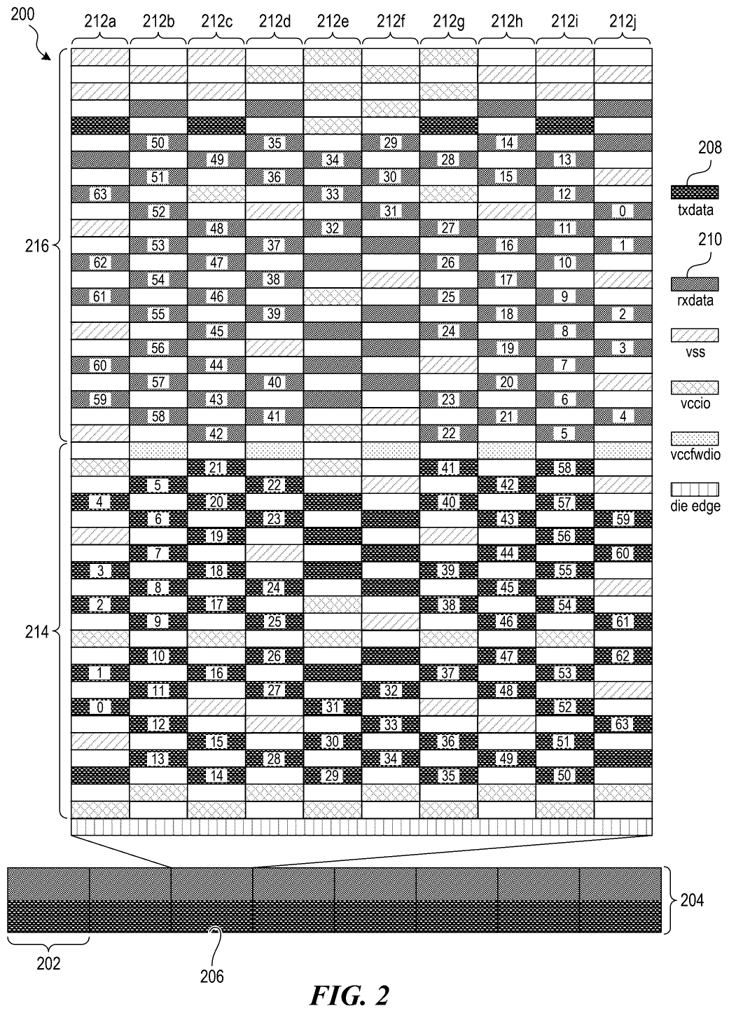

FIG. 2 is an illustration of a bump map 200 of a UCIe interface 202. As illustrated in FIG. 2, the UCIe interface 202 may be one of multiple independent UCIe interfaces (eight illustrated in FIG. 2) of an interface die 204 of an HBM device in a SiP device. The UCIe interfaces 202 may be located on a shoreline edge 206 of the interface die 204, nearest a host device (not shown) that communicates with the interface die 204 via the UCIe interfaces. Each of the UCIe interfaces 202 may provide the interconnect and communication interface between the host device and HBM device for one or more HBM channels. The interface die 204 may, for example, be the interface die 132, and the UCIe interfaces 202 may be part of the IO circuit 133, both illustrated in FIG. 1.

The transmit data bumps of all of the UCIe interfaces 202 are located closer to the shoreline edge 206 of the interface die 204 (as reflected by transmit shading 208), and the receive data bumps of all of the UCIe interfaces 202 are on the interior edge of the transmit data bumps (relative to the shoreline edge) and thus located further from the shoreline edge 206 of the interface die 204 (as reflected by receive shading 210). Further, all of the UCIe interfaces 202 of the interface die 204 conform to the same bump map 200, described in greater detail below.

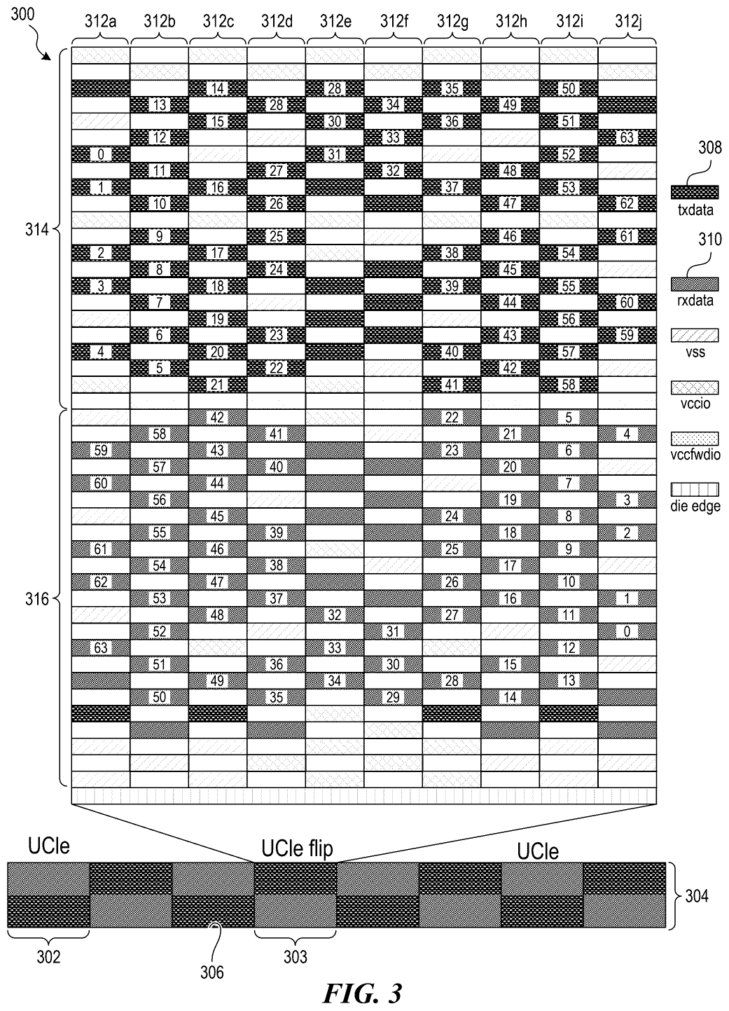

Bump map 200 illustrates the physical arrangement of signals at the physical boundary of one of the UCIe interfaces 202. The bump map 200 of FIG. 2 and other bump maps described below (illustrated in FIGS. 3-5) are illustrated using a “dead bug” view, which means the illustration reflects the viewer looking directly at the UCIe interconnect structures (e.g., micro bumps) facing up, as if the interface die was flipped like a “dead bug. ” The bump map 200 may conform (e.g., match the physical arrangement of) a bump map specified by one or more specific versions of the UCIe specification, such as UCIe 1.0, UCIe 1.1, UCIe 2.0, and/or future versions of UCIe. A host (not shown) may also use a UCIe-specified bump map (e.g., as defined by UCIe 1.0, UCIe 1.1, UCIe 2.0, and/or future versions of UCIe), that matches the bump map 200 for one or more of its UCIe interfaces.

The bump map 200 illustrates a 10-column arrangement that includes column 212a (corresponding to the left-most column in the dead bug view) to column 212j (corresponding to the right-most column in the dead bug view) (i.e., 10 total columns, 212a-212j). The bump map 200 further illustrates an “x64” configuration, associated with a 64-bit data width, with 64 bits of receive data signals (rxdata0-rxdata63) and 64 bits of transmit data signals (txdata0-txdata63). In the example illustrated in FIG. 2, column 212a includes the uppermost 5 bits of receive data (rxdata59-rxdata63, as illustrated by the bit indicators in the receive shading 210 of bump map 200) and the lowermost 5 bits of transmit data (txdata0-txdata4, as illustrated by the bit indicators in the transmit shading 208 of bump map 200), while other columns include other bits of the transmit and receive data signals.

As reflected in FIG. 2, all of the transmit data signal bumps are located in a transmit data region 214 of the bump map 200, and all of the receive data signal bumps are located in a receive data region 216 of the bump map 200. For example, the transmit data region 214 may span all columns 212a-212j of the bump map 200 and occupy approximately half of the rows of the bump map 200, and the receive data region 216 may span all columns 212a-212j of the bump map 200 and occupy approximately the other half of the rows of the bump map 200. Further, the transmit data region 214 may be closer to the die edge, and the receive data region 216 may be further from the die edge (as also reflected in interface die 204 and the transmit shading 208 and receive shading 210 illustrated therein, as described above). That is, the receive data region 216 may be characterized as being located on the “interior edge” of the transmit data region 214, in that it is located more towards the interior of the die and away from the die edge.

The physical arrangement of transmit data signal bumps and receive data signal bumps as shown in the example of bump map 200, and the way those signals are localized to distinct transmit data regions 214 and receive data regions 216, respectively, can lead to various challenges. For example, HBM workloads are often characterized by periods of activity in which a host device is sending only read commands or only write commands. Due the manner in which the transmit data signal bumps and receive data signal bumps are localized, as described above, these workload patterns can create hotspots in the UCIe interfaces 202 (for example, thermal hotspots in transmit data region 214 when a host device is issuing only read commands, or thermal hotspots in a receive data region 216 when a host device is issuing only write commands). These thermal hotspots can increase the operating temperature of the UCIe interfaces 202, interface die 204, and/or HBM device, resulting in temperatures that exceed acceptable operational levels for those devices. Such conditions can threaten to undermine the operation of the HBM device and/or interface die 204 and/or UCIe interfaces 202 therein (e.g., undermining data retention rates, requiring increased refresh rates, and/or the like) and/or connections within the SiP device (e.g., breaking connections between the HBM device and the base substrate, breaking connections in the signal TSVs, damaging circuits in the interface die 204 and/or the memory dies, and/or the like).

HBM devices with improved-thermal bump maps, and related systems and methods that address the shortcomings discussed above, are disclosed herein. As discussed in greater detail below, the HBM devices of the present technology employ UCIe interfaces with one or more bump maps that organize the physical arrangements of transmit data signal bumps and receive data signal bumps in a more distributed manner on the HBM interface die's shoreline edge nearest a host device. That is, embodiments of the present technology reduce the localization and concentration of all transmit data signal bumps to a first region of an HBM interface die (e.g., a shoreline edge, of the interface die, nearest a host device) and the localization of all receive data signal bumps to a second region of the HBM interface die (e.g., still localized to the shoreline edge, but on the interior side of the first region) as described above (e.g., with reference to FIGS. 1 and 2). Since, as described in greater detail below, in HBM devices of the present technology the transmit data signal bumps and receive data signal bumps are more distributed within the shoreline edge of the interface die, the concentration of thermal hotspots during periods of host writes and/or host reads is also reduced.

In some embodiments, HBM devices of the present technology, with improved-thermal bump maps, integrate UCIe interfaces with two or more different bump maps (e.g., one or more UCIe interfaces of the interface die conform to a first bump map, and one or more UCIe interfaces of the interface die conform to a second bump map), where the different bump maps locate the transmit data signal bumps and receive data signal bumps at different locations within each UCIe interface. That is, for example, a first bump map may locate transmit data signal bumps at a first region closest to the shoreline edge and the receive data signal bumps at a second region that is on the interior (to the die side) of the first region, while a second bump map may locate receive data signal bumps at the first region closest to the shoreline edge and the transmit data signal bumps at the second region that is on the interior side of the first region. In other words, in said embodiments, transmit data signal bumps and receive data signal bumps may be localized within an individual UCIe interface, but the use of UCIe interfaces with different bump maps disperses the overall distribution of transmit data signal bumps and receive data signal bumps along the shoreline edge.

In some embodiments, HBM devices of the present technology, with improved-thermal bump maps, integrate UCIe interfaces with a bump map in which transmit data signal bumps and receive data signal bumps are distributed through the UCIe interface. For example, whereas conventional UCIe interfaces may use a bump map in which all the transmit data signal bumps are localized to a first region and all of the receive data signal bumps are localized to a second region (e.g., the transmit data region 214 and receive data region 216 of bump map 200, as illustrated in FIG. 2), in improved-thermal bump maps of the present technology, the transmit data signal bumps and receive data signal bumps are more dispersed at the boundary of the UCIe interface, such that write command and read commands from a host device do not cause such localized thermal hotspots to occur. That is, as described in greater detail below, the placement of individual transmit data signal bumps and receive data signal bumps may be rearranged (as compared to a conventional UCIe interface and conventional bump map) to achieve a greater spatial distribution of the signals.

In some embodiments of the present technology in which the improved-thermal bump map arranges the transmit data signal bumps and receive data signal bumps with a greater spatial distribution (as compared to a conventional bump map) within a UCIe interface, the signals may be arranged in a manner that improves interoperability with conventional UCIe interfaces that adopt a conventional bump map. For example, if in the bump map of a conventional UCIe interface a column has a specific set of transmit data signal bits and a specific set of receive data signal bits, then in a UCIe interface with an improved-thermal bump map the same transmit data signal bits and receive data signal bits may be located in the same column, however rearranged to be in different rows (as compared to the conventional bump map) within that column. For example, if column 0 (e.g., the left-most column) of the bump map of a conventional UCIe interface includes rxdata59-rxdata63 and txdata0-txdata4, then column 0 of an improve-thermal bump map (for UCIe interfaces of the precent technology) may also include rxdata59-rxdata63 and txdata0-txdata4 (however at different row locations than in the conventional UCIe interface).

In some embodiments of the present technology in which the improved-thermal bump map arranges the transmit data signal bumps and receive data signal bumps with a greater spatial distribution (as compared to a conventional bump map) within a UCIe interface, the rearranged signals may still be placed in consecutive bit order. That is, and as explained in greater detail, the rearranged transmit data signal bumps and the rearranged receive data signal bumps may still support a transmit data chain and a receive data chain, respectively. Such chaining of consecutive bits enables lane repair, reversal, and/or other UCIe features.

In some embodiments of the present technology, the improved-thermal bump map of at least one UCIe interface of an HBM device does not conform to the UCIe specification (e.g., the physical arrangement of signals at the UCIe interface differs from any UCIe-specified arrangements), but the at least one UCIe interface of the HBM device is communicably coupled to a UCIe interface of a host device. In some embodiments, the improved-thermal bump map of all UCIe interfaces of an HBM device does not conform to the UCIe specification, and the HBM UCIe interfaces are communicably coupled to UCIe interfaces of a host device. In some embodiments, the UCIe interface of the host device does conform to a UCIe specification. In some embodiments in which a non-standard UCIe interface of an HBM device is communicably coupled to a standard UCIe interface of a host device, the base substrate (for example, silicon interposer) on which the HBM device and host device are carried may route the signals such that UCIe signals to/from the host device land on the appropriate interconnect structure of the UCIe interface of the HBM device.

Additional details of the HBM devices with improved-thermal bump maps, and related systems and methods, are discussed below with reference to FIGS. 3-5.

FIG. 3 is an illustration of bump map 300 of a flipped UCIe interface 303 configured in accordance with some embodiments of the present technology. The bump map 300 and flipped UCIe interface 303 may be used in an HBM device that is part of a SiP device. As described in greater detail below, the flipped UCIe interface 303 (and corresponding bump map 300) may be “flipped” in comparison to a UCIe interface 302 (for example, a conventional UCIe interface and corresponding bump map, as illustrated in FIG. 2).

The flipped UCIe interface 303 and UCIe interface 302 may each be one of multiple independent UCIe interfaces of an interface die 304 of an HBM device in a SiP device. For example, as illustrated in FIG. 3, the interface die 304 includes four UCIe interfaces 302 and four flipped UCIe interfaces 303, all of which are positioned on a shoreline edge 306, of the interface die 304, nearest a host device (not shown) that communicates with the interface die 304 via the UCIe interfaces. Each of the UCIe interfaces 302 and flipped UCIe interfaces 303 may provide the interconnect and communication interface between the host device and HBM device for one or more HBM channels.

The transit data bumps of all of the UCIe interfaces 302 may be located closer to the shoreline edge 306 of the interface die 304 (as reflected by transmit shading 308), and the receive data bumps of all of the UCIe interfaces 302 may be on the interior edge of the transmit data bumps (relative to the shoreline edge), and thus located further from the shoreline edge 306 of the interface die 304 (as reflected by receive shading 310). In contrast, the arrangement of the transmit data bumps and receive data bumps of the flipped UCIe interfaces 303 are flipped with respect to which is positioned closed to the shoreline edge 306. That is, as illustrated in FIG. 3, the receive data bumps of all of the flipped UCIe interfaces 303 may be positioned closer to shoreline edge 306 (reflected by receive shading 310), and the transmit data bumps of all of the flipped UCIe interfaces 303 may be positioned on the interior edge of the receive data bumps (reflected by transmit shading 308).

As illustrated in FIG. 3, in some embodiments, the UCIe interfaces 302 and flipped UCIe interfaces 303 can be placed in alternating fashion to achieve a checkerboard pattern of transmit data bumps and receive data bumps along and/or adjacent to the shoreline edge 306 of the interface die 304. In some embodiments, the UCIe interfaces 302 and flipped UCIe interfaces 303 may be placed in other patterns (e.g., two instances of UCIe interfaces 302, followed by two instances of flipped UCIe interfaces 303, followed by two instances of UCIe interfaces 302, etc.) that disperse the placement of transmit data bumps and shoreline data bumps along/adjacent to the shoreline edge 306. It will be appreciated that by utilizing both UCIe interfaces 302 and flipped UCIe interfaces 303 on the shoreline edge 306 of the interface die 304 (for example, to create a checkerboard pattern of transmit and receive data bumps, as shown), the concentration of exclusively transmit data bumps and exclusively receive data bumps is reduced, thereby reducing the occurrences of thermal hotspots.

Bump map 300 illustrates the physical arrangement of signals at the physical boundary of one of the flipped UCIe interfaces 303. The bump map 300 illustrates a 10-column arrangement that includes column 312a (corresponding to the left-most column in the dead bug view) to column 312j (corresponding to the right-most column in the dead bug view) (i.e., 10 total columns, 312a-312j). The bump map 300 further illustrates an “x64” configuration (indicating a 64-bit data width), with 64 bits of receive data signals (rxdata0-rxdata63) and 64 bits of transmit data signals (txdata0-txdata63).

As illustrated in FIG. 3, all of the transmit data signal bumps are located in a transmit data region 314, and all of the receive data signal bumps are located in a receive data region 316. For example, the transmit data region 314 may span all columns 312a-312j of the bump map 300 and occupy approximately half of the rows of the bump map 300, and the receive data region 316 may span all columns 312a-312j of the bump map 300 and occupy approximately the other half of the rows of the bump map 300. In contrast to a conventional UCIe interface that conforms to a UCIe specification (for example, the bump map 200 illustrated in FIG. 2), in the bump map 300 of an improved-thermal UCIe interface, the receive data region 316 is located closest to the die edge, and the transmit data region 314 is located on the interior edge (e.g., towards the die center) of the receive data region 316. That is, the placement of the transmit data signal bumps and receive data signal bumps are flipped or mirrored, in the vertical dimension (from the die edge to the die center) along a center axis, as compared to the bump map of a conventional UCIe interface. As described in greater detail below, in some embodiments of the present technology, at least one of the columns 312a-312j (including all of columns 312a-312j) of bump map 300 includes bumps for the same signals located in the corresponding column in a conventional bump map (e.g., bump map 200 of FIG. 2), but the order of the bumps is reversed.

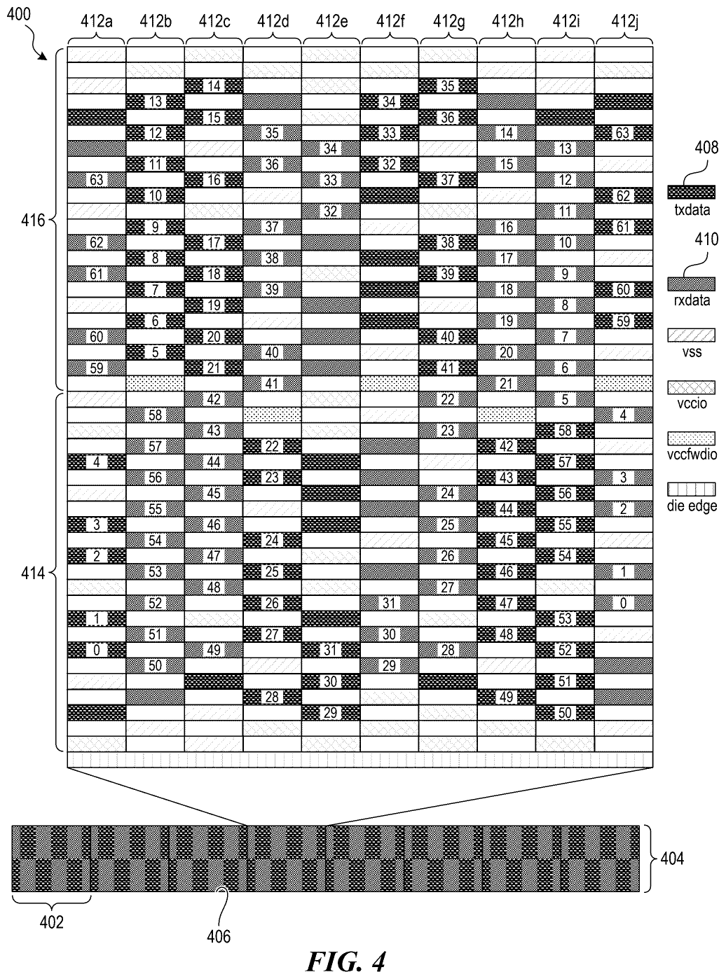

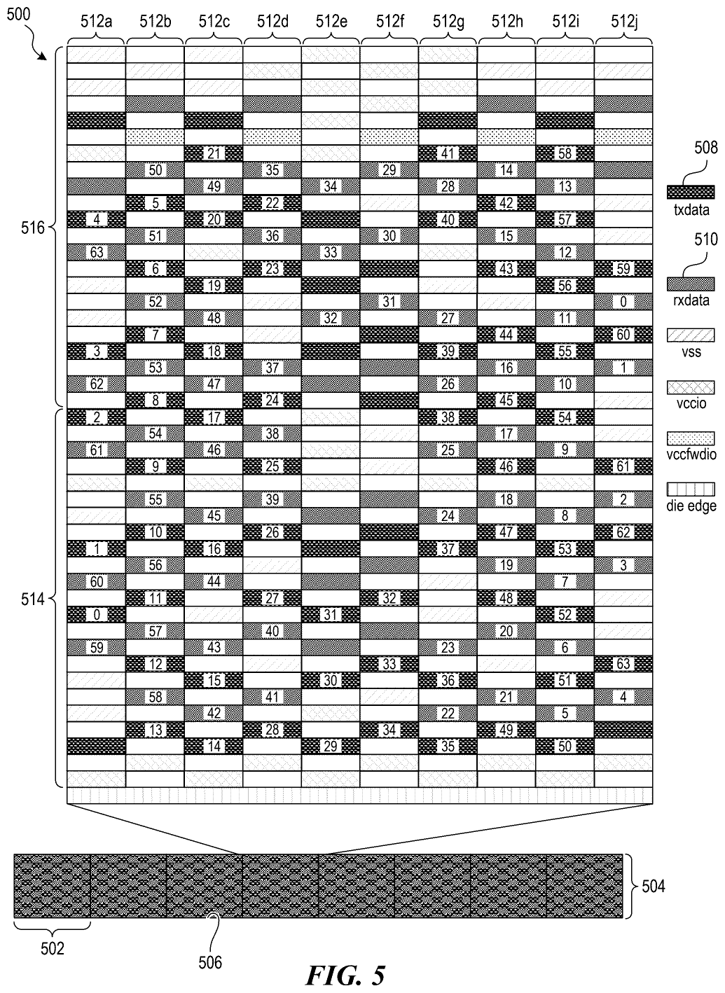

As described above, in some embodiments of the present technology, the improved-thermal bump maps, improved-thermal UCIe interfaces, and/or improved-thermal HBM devices interleave the transmit data signal bumps and receive data signal bumps (for example, in a checkerboard pattern) along/adjacent to the shoreline edge of an interface die, while within each individual UCIe interface the transmit data signal bumps and receive data signal bumps are localized to specific regions (for example, as illustrated in FIG. 3). In some embodiments of the present technology, and as described in greater detail below (with references to FIGS. 4-5), the improved-thermal bump maps, improved-thermal UCIe interfaces, and/or improved-thermal HBM devices achieve interleaving within individual UCIe interfaces. That is, the placement of transmit data signal bumps and receive data signal bumps are located in a more dispersed, distributed, and/or interleaved fashion within at least one of each of the UCIe interfaces.

FIG. 4 is an illustration of a bump map 400 of an improved-thermal UCIe interface 402 configured in accordance with further embodiments of the present technology. The improved-thermal UCIe interface 402 may be one of multiple independent UCIe interfaces (eight illustrated in FIG. 4) of an interface die 404 of an HBM device in a SiP device. The improved-thermal UCIe interface 402 may be located on a shoreline edge 406 of the interface die 404, nearest a host device (not shown) that communicates with the interface die 404 via the UCIe interfaces.

As reflected in the illustration of the interface die 404, the transmit data bumps (corresponding to the transmit shading 408) and the receive data bumps (corresponding to the receive shading 410) are interleaved within each improved-thermal UCIe interface 402 of the interface die 404. In some embodiments, and as described in greater detail below, the interleaving illustrated by the interface die 404 may be achieved with UCIe interface bump maps in which some columns locate transmit data bumps closer to a die edge, and other columns locate receive data bumps closer to a die edge.

Bump map 400 illustrates the physical arrangement of signals at the physical boundary of one of the improved-thermal UCIe interfaces 402. The bump map 400 illustrates a 10-column arrangement that includes column 412a (corresponding to the left-most column in the dead bug view) to column 412j (corresponding to the right-most column in the dead bug view) (i.e., 10 total columns, 412a-412j). The bump map 400 further illustrates an “x64” configuration (indicating a 64-bit data width), with 64 bits of receive data signals (rxdata0-rxdata63) and 64 bits of transmit data signals (txdata0-txdata63).

Bump map 400 includes an outer region 414 that is closest to the die edge and an inner region 416 that is on the inner (towards the die center) edge of the outer region 414. As illustrated in FIG. 4, in some embodiments, the outer region 414 and/or the inner region 416 may span all columns 412a-412j of the bump map 400. Further, at least one of the columns 412a-412j may be mirrored or flipped in the vertical dimension along a center axis as compared to at least another of the columns 412a-412j, with respect to in which regions the transmit data signal bumps and receive data signal bumps are located. That is, for example, in column 412a the receive data signal bumps are in the inner region 416, while in column 412b the receive data signal bumps are in the outer region 414. In some embodiments, two or more consecutive columns may be mirrored. For example, as illustrated in FIG. 4, columns 412b, 412c, 412f, 412g are mirrored. It will be appreciated that other repeating patterns and arrangements (e.g., alternating between flipped and conventional columns) are also within the scope of the present technology. In some embodiments, the transmit data signal bumps and receive data signal bumps are placed so that the outer region 414 and/or inner region 416 include an equivalent number of transmit data signal bumps and receive data signal bumps.

FIG. 5 is an illustration of a bump map 500 of an improved-thermal UCIe interface 502 configured in accordance with still further embodiments of the present technology. The improved-thermal UCIe interface 502 may be one of multiple independent UCIe interfaces (eight illustrated in FIG. 5) of an interface die 504 of an HBM device in a SiP device. The improved-thermal UCIe interface 502 may be located on a shoreline edge 506 of the interface die 405, nearest a host device (not shown) that communicates with the interface die 504 via the UCIe interfaces.

As reflected in the illustration of the interface die 504, the transmit data bumps (corresponding to the transmit shading 508) and the receive data bumps (corresponding to the receive shading 510) are interleaved within each improved-thermal UCIe interface 502 of the interface die 504. In some embodiments, and as described in greater detail below, the interleaving illustrated by the interface die 504 may be achieved with UCIe interface bump maps in which the transmit data bumps and receive data bumps are interleaved within the improved-thermal UCIe interface 502 in a checkerboard pattern.

Bump map 500 illustrates the physical arrangement of signals at the physical boundary of one of the improved-thermal UCIe interfaces 502. The bump map 500 illustrates a 10-column arrangement that includes column 512a (corresponding to the left-most column in the dead bug view) to column 512j (corresponding to the right-most column in the dead bug view) (i.e., 10 total columns, 512a-512j). The bump map 500 further illustrates an “x64” configuration (indicating a 64-bit data width), with 64 bits of receive data signals (rxdata0-rxdata63) and 64 bits of transmit data signals (txdata0-txdata63).

Bump map 500 includes an outer region 514 that is closest to the die edge and an inner region 516 that is on the inner (towards the die center) edge of the outer region 514. As illustrated in FIG. 5, in some embodiments the outer region 514 and/or the inner region 516 may span all columns 512a-512j of the bump map 500. Further, at least one of the columns, within at least one of the regions, include at least one transmit data signal bump and at least one receive data signal bump. For example, as illustrated in FIG. 5, column 512a of the outer region 514 includes bumps for transmit data signal bits 0 and 1, and includes bumps for receive data signal bits 59, 60, and 61. In some embodiments, every region of every column (e.g., both outer region 514 and inner region 516 of columns 512a-512j) includes at least one transmit data signal bump and at least one receive data signal bump. In some embodiments of the present technology transmit data signal bumps and receive data signal bumps are interleaved within a column, where transmit data signal bumps and receive data signal bumps are placed in alternating rows. For example, as illustrated in FIG. 5, column 512a of the outer region 512 includes bumps in the following order (starting from the outer or shoreline edge): bump for receive data signal bit 59, bump for transmit data signal bit 0, bump for receive data signal bit 60, bump for transmit data signal bit 1, bump for receive data signal bit 61, etc. In some embodiments of the present technology, transmit data signal bumps and receive data signal bumps that are interleaved and/or placed in alternating rows may have bumps for other signals (e.g., other than transmit data and receive data) placed therebetween. For example, as illustrated in FIG. 5, in column 512a of the outer region 516 the bump for receive data signal bit 63 and the bump for the transmit data signal bit 3 may be characterized as interleaved (with respect to transmit data signals and receive data signals) even though bumps for other signals (for example, Vss as illustrated in FIG. 5) may be located in between.

In some embodiments of the present technology, at least one column of the bump map of an improved-thermal UCIe interface includes bumps for the same transmit data signals and receive data signals that are located in the same column in a conventional UCIe interface. For example, as illustrated in FIGS. 2-5, column 312a of bump map 300, column 412a of bump map 400, and column 512a of bump map 500 (illustrating embodiments of the present technology) include bumps for the same transmit data signal bits and receive data signal bits as column 212a of bump map 200 (illustrating a conventional UCIe interface), but (as described above) they may be located in different order within the column. In some embodiments, all columns of an improved-thermal bump map used in an improved-thermal UCIe interface include bumps for the same transmit data signals and receive data signals as located in the corresponding columns of a conventional UCIe interface.

In some embodiments of the present technology, bumps for transmit data signals are placed in consecutive bit order, and bumps for receive data signals are placed in consecutive bit order. For example, referring to FIG. 4, outer region 414 of column 412a includes bumps for transmit data signals bits 0 through 4. In some embodiments, the consecutive bit ordering spans columns (which may or may not be adjacent) in the same or different region. For example, referring again to FIG. 4, bumps for transmit data signals bits 5-13 are located in column 412b (adjacent to column 412a discussed immediately above) in inner region 416. A consecutive bit ordered path may then be created from the bump of transmit data signal bit 0 to the bump of transmit data signal bit 13 without striking the bump of any intervening transmit data signal bits. As a further example, still referring to FIG. 4, the consecutive bit ordered path can continue to bumps for transmit data signal bits 14-21, located in columns 412c (adjacent to column 412b) and inner region 416 (the same regions in bumps for transmit data signals bits 5-13 are located).

Although embodiments of the present technology have been described with reference to UCIe interfaces with 10-column bump maps in an x64 configuration, the disclosed technology is not so limited. For example, improved-thermal bump maps may be used in UCIe interfaces with a different number of columns (e.g., 16 columns or eight columns) and/or different data-width configurations (e.g., x16 or x32 indicates 16 bits or 32 bits, respectively).

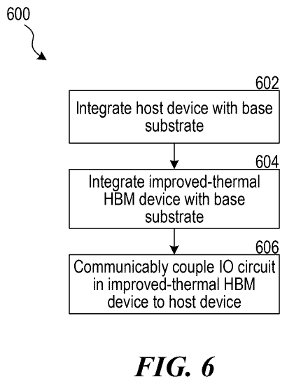

FIG. 6 is a flow diagram of a process 600 for manufacturing an improved-thermal SiP device in accordance with some embodiments of the present technology. The process 600 can be implemented by a single manufacturing apparatus and/or split between multiple manufacturing apparatuses to construct improved-thermal SiP devices according to the embodiments discussed above.

The process 600 begins at block 602 by integrating a host device with a base substrate of the improved-thermal SiP device. In various embodiments, the base substrate can be a silicon interposer, a substrate of organic material, a substrate of inorganic material, and/or any other suitable material that provides external connections to the host device and/or provides mechanical support for the components of an improved-thermal SiP device. Integrating the host device with the base substrate can include bonding the host device to the base substrate via one or more interconnect structures (e.g., solder structures, conductive posts, and/or the like) and/or forming one or more metal-metal bonds directly between bond pads in the base substrate and bond pads in the host device.

At block 604, the process 600 includes integrating an improved-thermal HBM device with the base substrate. Similar to the discussion above, integrating the improved-thermal HBM device with the base substrate can include bonding the improved-thermal HBM device to the base substrate via one or more interconnect structures and/or forming one or more metal-metal bonds directly between bond pads in the base substrate and bond pads in the improved-thermal HBM device. In some embodiments, the process 600 can execute block 604 before executing all (or some of) block 602 to integrate the improved-thermal HBM device with the base substrate before integrating the host device with the base substrate and/or before integrating an IO die with the host device. In some embodiments, the process 600 can execute block 604 at generally the same time as block 602 to integrate the host device and the improved-thermal HBM device with the base substrate at generally the same time.

At block 606, the process 600 includes communicably coupling an IO circuit in the improved-thermal HBM device (e.g., one or more UCIe interfaces in an interface die illustrated in FIGS. 3-5) to the host device. As discussed in more detail above, the communicable coupling can be accomplished through one or more communication channels in the base substrate.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately,” “generally,” and/or “about” are used herein to mean within at least 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

I/We claim:

1. A system-in-package (SiP) device, comprising:
a base substrate;
a host device carried by the base substrate; and
a high-bandwidth memory (HBM) device carried by the base substrate, wherein the HBM device comprises an interface die and a stack of one or more memory dies carried by the interface die, and wherein the interface die comprises an input/output (IO) circuit, the IO circuit comprising:
a first Universal Chiplet Interconnect Express (UCIe) interface communicably coupled to the host device, wherein the first UCIe interface comprises a first interconnect structure for a first transmit data signal in a first region adjacent to an edge of the interface die, and further comprises a second interconnect structure for a first receive data signal in a second region adjacent to an interior edge of the first region; and
a second UCIe interface communicably coupled to the host device, wherein the second UCIe interface comprises a third interconnect structure for a second receive data signal in the first region adjacent to the edge of the interface die, and further comprises a fourth interconnect structure for a second transmit data signal in the second region adjacent to the interior edge of the first region.

2. The SiP device of claim 1, wherein the first UCIe interface and the second UCIe interface are operable to communicate, with the HBM device, independently of each other.

3. The SiP device of claim 1, wherein the first UCIe interface conforms to a UCIe specification.

4. The SiP device of claim 1, wherein the second UCIe interface does not conform to a UCIe specification.

5. The SiP device of claim 4, wherein the second UCIe interface is communicably coupled to the host device by a host UCIe interface, and wherein the host UCIe interface conforms to the UCIe specification.

6. The SiP device of claim 1, wherein the IO circuit comprises a first set of UCIe interfaces with a first bump map and a second set of UCIe interfaces with a second bump map.

7. The SiP device of claim 6, wherein the first UCIe interface is one of the first set of UCIe interfaces, and the second UCIe interface is one of the second set of UCIe interfaces.

8. The SiP device of claim 6, wherein the UCIe interfaces of the first set of UCIe interfaces and the UCIe interfaces of the second set of UCIe interfaces are placed in alternating order along the edge of the interface die.

9. The SiP device of claim 1, wherein the first UCIe interface and the second UCIe interface are each communicably coupled to the host device by a data width comprising a plurality of data bits, wherein a first column of the first UCIe interface comprises a plurality of interconnect structures for transmit data signals corresponding to a first set of bits within the plurality of data bits, and wherein a second column of the second UCIe interface comprises a plurality of interconnect structures for transmit data signals corresponding to the first set of bits within the plurality of data bits.

10. The SiP device of claim 9, wherein the first column and the second column are at a same location in the respective first UCIe interface and second UCIe interface.

11. A high-bandwidth memory (HBM) device, comprising:
a stack of one or more memory dies; and
an interface die carrying the stack of one or more memory dies, the interface die comprising an input/output (IO) circuit, the IO circuit comprising:
a Universal Chiplet Interconnect Express (UCIe) interface communicably coupled to a host device by a plurality of transmit data interconnect structures and a plurality of receive data interconnect structures, wherein locations of each of the plurality of transmit data interconnect structures and the plurality of receive data interconnect structures on the UCIe interface are specified by a bump map, wherein the bump map comprises:
a plurality of columns and a plurality of rows; and
a region spanning the plurality of columns and a subset of the plurality of rows, wherein a first subset of the plurality of columns in the region comprises receive data interconnect structures and does not include transmit data interconnect structures, and a second subset of the plurality of columns in the region comprises transmit data interconnect structures and does not include receive data interconnect structures.

12. The HBM device of claim 11, wherein at least two columns of the first subset of the plurality of columns are adjacent to each other.

13. The HBM device of claim 12, wherein a first of the at least two columns comprises a receive data interconnect structure associated with a first data bit, a second of the at least two columns comprises a receive data structure associated with a second data bit, and the first data bit and the second data bit are consecutive data bits.

14. The HBM device of claim 11, wherein at least two columns of the second subset of the plurality of columns are adjacent to each other.

15. The HBM device of claim 14, wherein a first of the at least two columns comprises a transmit data interconnect structure associated with a first data bit, a second of the at least two columns comprises a transmit data structure associated with a second data bit, and the first data bit and the second data bit are consecutive data bits.

16. A high-bandwidth memory (HBM) device, comprising:
a stack of one or more memory dies; and
an interface die carrying the stack of one or more memory dies, the interface die comprising an input/output (IO) circuit, the IO circuit comprising:
a Universal Chiplet Interconnect Express (UCIe) interface communicably coupled to a host device by a plurality of transmit data interconnect structures and a plurality of receive data interconnect structures, wherein locations of each of the plurality of transmit data interconnect structures and the plurality of receive data interconnect structures on the UCIe interface are specified by a bump map, wherein the bump map comprises:
a plurality of columns and a plurality of rows; and
wherein a first column from the plurality of columns comprises a subset of the plurality of transmit data interconnect structures and a subset of the plurality of receive data interconnect structures, and wherein the subset of transmit data interconnect structures and the subset of receive data interconnect structures are interleaved in alternating rows.

17. The HBM device of claim 16, wherein each of the subset of transmit data interconnect structures are associated with a data bit, and wherein the subset of transmit data interconnect structures are placed in the first column in an order based on the corresponding data bits.

18. The HBM device of claim 16, wherein each of the subset of receive data interconnect structures are associated with a data bit, and wherein the subset of receive data interconnect structures are placed in the first column in an order based on the corresponding data bits.

19. The HBM device of claim 16, wherein the UCIe interface bump map comprises 8, 10, or 16 columns.

20. The HBM device of claim 19, wherein all of the columns comprise transmit data interconnect structures and receive data interconnect structures interleaved in alternating rows.
